(19) United States
(12) Patent Application Publication
(10) Pub. No.: US 2024/0306363 A1
(43) Pub. Date: Sep. 12, 2024

(54) STACKED CAPACITOR, METHOD FOR MAKING THE SAME AND MEMORY DEVICE

(71) Applicant: HeFeChip Corporation Limited, Hong Kong (CN)

(72) Inventor: Geeng-Chuan CHERN, Cupertino, CA (US)

(21) Appl. No.: 18/127,321

(22) Filed: Mar. 28, 2023

(30) Foreign Application Priority Data
Mar. 6, 2023 (CN) 202310206683.5

(51) Int. Cl. H10B 12/00

(52) U.S. Cl. CPC H10B 12/033; H10B 12/315

(57) ABSTRACT

A multilayer capacitor, a method for making the multilayer capacitor, and a memory device are disclosed by the present invention. The multilayer capacitor made by the method is connected to a capacitor terminal and includes a multilayer fin structure including horizontal and vertical fin elements. A first conductive layer covers a surface of the multilayer fin structure and thereby has a large surface area. A capacitor dielectric layer covers a surface of the first conductive layer, and a second conductive layer covers the capacitor dielectric layer. In this way, the multilayer capacitor has desirably large capacitance. In addition, in the method, after a layer stack is formed, it is processed into the multilayer fin structure by self-aligned anisotropic and isotropic etch, which do not require the use of any photomask or the deposition of any additional layer, resulting in low manufacturing cost. The memory device includes the multilayer capacitor.

### CROSS-REFERENCE TO RELATED APPLICATION

This application claims the priority of Chinese patent application number 202310206683.5, filed on Mar. 6, 2023, the entire contents of which are incorporated herein by reference.

### TECHNICAL FIELD

The present invention relates to the field of semiconductor technology and, in particular, to a stacked capacitor, a method for making the stacked capacitor, and a memory device.

### BACKGROUND

Dynamic random-access memory (DRAM) stores electric charge on capacitors and maintains the electric charge on the capacitors at a readable level through periodic refresh operations. The trend toward faster operation requires DRAM capacitors to have higher capacitance.

In order to satisfy the demand for higher capacitance, stacked capacitors or trench capacitors are increasingly used because they can provide a large internal capacitor area and reduce crosstalk between DRAM cells. However, with the increasingly higher level of integration of DRAM devices, DRAM cells are shrinking in both size and area, making it more and more difficult to form trench capacitors with higher aspect ratios. This presents a great challenge to the fabrication of trench capacitors. Compared with trench capacitors, stacked capacitors are less demanding in terms of aspect ratio.

However, existing stacked capacitors still need further improvement in terms of capacitance.

### SUMMARY OF THE INVENTION

The present invention provides a method capable for making a stacked capacitor with improved capacitance. Also provided are such a stacked capacitor and a memory device.

In one aspect, the present invention provides a method for making a stacked capacitor, comprising:
providing a capacitor terminal formed on a surface of a first interlayer insulating layer;
forming a second interlayer insulating layer over the capacitor terminal and the first interlayer insulating layer;
forming an opening penetrating through the second interlayer insulating layer, wherein the capacitor terminal is exposed in the opening;
forming a layer stack by stacking a first material layer and a second material layer over a surface of the second interlayer insulating layer and over an internal surface of the opening and repeating the stacking at least one time;
removing portions of the second material layers and portions of the first material layers by performing a self-aligned anisotropic etch, wherein a remaining layer stack covers a sidewall of the opening and exposes the second interlayer insulating layer and the capacitor terminal;
forming a multilayer fin structure connected to the sidewall of the opening by performing an isotropic etch that is used to etch back the first material layers in the layer stack and to expose surfaces of portions of the second material layers, wherein the multilayer fin structure comprises horizontal fin elements and vertical fin elements formed by portions of the second material layers; and
forming a first conductive layer, a capacitor dielectric layer and a second conductive layer, wherein the first conductive layer covers a surface of the multilayer fin structure and a surface of the capacitor terminal exposed in the opening, wherein the capacitor dielectric layer covers a surface of the first conductive layer, the second conductive layer covering the capacitor dielectric layer.

In another aspect, the present invention provides a stacked capacitor, comprising:
a capacitor terminal formed on a surface of a first interlayer insulating layer;
a second interlayer insulating layer formed over the first insulating layer, wherein the second interlayer insulating layer has an opening penetrating therethrough, and wherein the capacitor terminal is exposed in the second interlayer insulating layer;
a multilayer fin structure connected to a sidewall of the opening and exposing the capacitor terminal at a bottom of the opening, wherein the multilayer fin structure comprises horizontal fin elements and vertical fin elements;
a first conductive layer covering a surface of the multilayer fin structure and a surface of the exposed capacitor terminal;
a capacitor dielectric layer covering a surface of the first conductive layer; and
a second conductive layer covering the capacitor dielectric layer.

In yet another aspect, the present invention provides a memory device comprising the stacked capacitor.

The stacked capacitor made by the method of the present invention is connected to the capacitor terminal and includes the multilayer fin structure including the horizontal and vertical fin elements. The first conductive layer covers the surface of the multilayer fin structure and thereby has a large surface area. In this way, the stacked capacitor has desirably large capacitance. In addition, in the method, the layer stack is formed by repeatedly depositing the first and second material layers and then processed into the multilayer fin structure by the self-aligned anisotropic and isotropic etch, which do not require the use of any photomask or the deposition of any additional layer, resulting in low manufacturing cost.

In the stacked capacitor and the memory device provided in the present invention, the multilayer fin structure can include multiple horizontal fin elements and multiple vertical fin elements. As a result, the first conductive layer covering the surface of the multilayer fin structure has a large surface area, which helps increase the capacitance of the stacked capacitor to a desired level. Further, the stacked capacitor can be fabricated at low cost.

### BRIEF DESCRIPTION OF THE DRAWINGS

FIG. 1 shows a schematic cross-sectional view of a structure resulting from the formation of a second interlayer insulating layer in a method for making a stacked capacitor according to an embodiment of the present invention.

FIG. 2 shows a schematic cross-sectional view of a structure resulting from the formation of openings penetrating through the second interlayer insulating layer in the method for making a stacked capacitor according to an embodiment of the present invention.

FIG. 3 shows a schematic cross-sectional view of a structure resulting from the formation of a layer stack in the method for making a stacked capacitor according to an embodiment of the present invention.

FIG. 4 shows a schematic cross-sectional view of a structure resulting from an etch performed on a topmost layer in the layer stack in the method for making a stacked capacitor according to an embodiment of the present invention.

FIG. 5 shows a schematic cross-sectional view of a structure resulting from an etch performed on a second topmost layer in the layer stack in the method for making a stacked capacitor according to an embodiment of the present invention.

FIG. 6 shows a schematic cross-sectional view of a structure resulting from an etch performed on a third topmost layer in the layer stack in the method for making a stacked capacitor according to an embodiment of the present invention.

FIG. 7 shows a schematic cross-sectional view of a structure resulting from an etch performed on a bottommost layer in the layer stack in the method for making a stacked capacitor according to an embodiment of the present invention.

FIG. 8 shows a schematic cross-sectional view of a structure resulting from an etch-back performed on first material layers in the method for making a stacked capacitor according to an embodiment of the present invention.

FIG. 9 shows a schematic cross-sectional view of a structure resulting from the formation of a first conductive layer in the method for making a stacked capacitor according to an embodiment of the present invention.

FIG. 10 shows a schematic cross-sectional view of a structure resulting from the formation of a capacitor dielectric layer and a second conductive layer in the method for making a stacked capacitor according to an embodiment of the present invention.

### DETAILED DESCRIPTION

Particular embodiments of the present invention will be described in greater detail below with reference to the accompanying drawings. It is to be understood that the figures are provided in a very simplified form not necessarily drawn to exact scale for the only purpose of facilitating easy and clear description of the embodiments. Additionally, the spatially relative terms are intended to encompass different orientations of the device in use or operation in addition to the orientation depicted in the figures. For example, if the device in the figures is inverted or otherwise oriented in (e.g., rotated), the exemplary term “over” can encompass an orientation of “under” and other orientations.

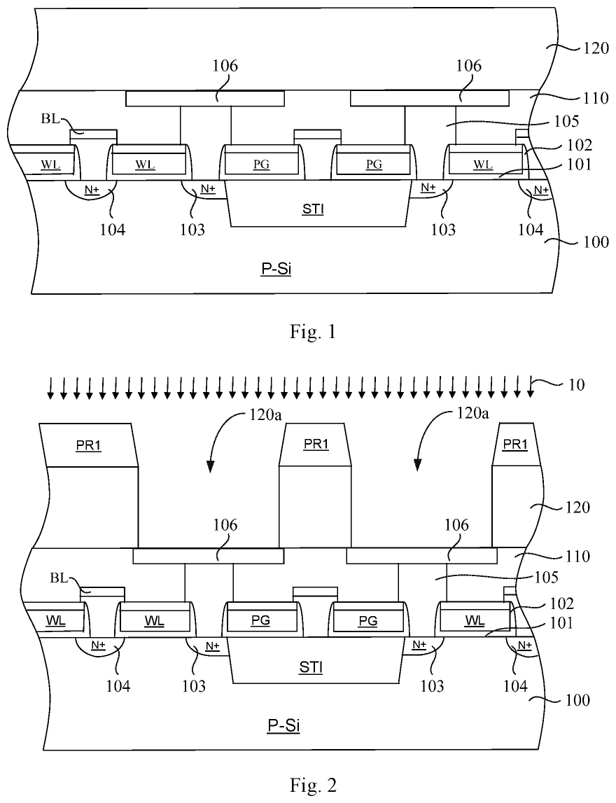

An embodiment of the present invention relates to a method for making a stacked capacitor. The method is described below with reference to FIGS. 1 to 10.

Referring to FIG. 1, capacitor terminals are formed on the surface of a first interlayer insulating layer 110 and a second interlayer insulating layer 120 is formed over the capacitor terminals and the first interlayer insulating layer 110.

The capacitor terminals and the first interlayer insulating layer 110 are, for example, formed on a semiconductor substrate 100. Each capacitor terminal is connected to a circuit such as an electronic component in or on the semiconductor substrate 100. The semiconductor substrate 100 is, for example, a silicon substrate, a germanium (Ge) substrate, a silicon germanium substrate, a silicon on insulator (SOI) substrate, a germanium on insulator (GOI) substrate or the like. As required by the design, dopant ions such as P-type or N-type ions may be injected into the semiconductor substrate 100. For example, the semiconductor substrate 100 may comprise isolation regions and active areas defined by the isolation regions. Source/drain regions may be formed in the active areas. At least one of the source/drain regions may be connected to one of the capacitor terminals.

Referring to FIG. 1, the stacked capacitors to be fabricated, for example, are used in a dynamic random-access memory (DRAM) device, and the semiconductor substrate 100 is, for example, a P-doped silicon substrate (P—Si). The semiconductor substrate 100 may undergo the following processes. At first, the isolation (e.g., shallow trench isolation (STI)) regions and the active areas are formed in the semiconductor substrate 100. A plurality of word lines WL are then formed on the semiconductor substrate 100, and some of the word lines WL are located above the active areas and serve as gates of MOS transistors and also some of the word lines WL are located above the isolation regions and serve as passing gates (PGs). A dielectric (e.g., silicon nitride) layer is formed on top surfaces of the word lines WL, and a gate dielectric layer 101 is formed between the word lines WL and the semiconductor substrate 100, and spacers 102 on sidewalls of the word lines WL and side walls of the gate dielectric layer 101. Subsequently, source regions 103 and drain regions 104 of the MOS transistors are formed in the active areas on opposite sides of the gates. The source regions 103 and drain regions 104 are, for example, heavily dope N-type (N+) regions optionally exposed in self-aligned contact holes delimited by the spacers 102. Afterwards, bit lines BL connected to the drain regions 104 are formed by filling the contact holes in which the drain regions 104 are exposed. Next, the first interlayer insulating layer 110 is deposited over the semiconductor substrate 100. The first interlayer insulating layer 110 may include silicon oxide, silicon nitride, silicon oxynitride, nitrogen-doped silicon carbide (NDC) or another dielectric material, or any combination thereof. Thereafter, the first interlayer insulating layer 110 is etched so that contact holes are formed therein, in which the source regions 103 are exposed, and upper portions of the contact holes are expanded to define ranges for the capacitor terminals. Following that, a conductive material is filled in the contact holes including the upper portions that define the ranges for the capacitor terminals, followed by a planarization thereby simultaneously forming, in the first interlayer insulating layer 110, contact plugs 105 and conductive plates 106 located on the contact plugs 105. The contact plugs 105 are connected to the source regions 103 at one end and to the conductive plates 106 at the other end. In other embodiments, the contact plugs 105 and the conductive plates 106 may not be formed simultaneously. A second interlayer insulating layer 120 is then deposited over the conductive plates 106 and the first interlayer insulating layer 110. The second interlayer insulating layer 120 may include silicon oxide, silicon nitride, silicon oxynitride, NDC or another dielectric material, or any combination thereof.

In this embodiment, the conductive plates 106 connected to the source regions 103 of the MOS transistors serve as the capacitor terminals.

Referring to FIG. 2, openings 120a penetrating through the second interlayer insulating layer 120 are formed, in which the capacitor terminals (here, the conductive plates 106) are exposed.

Specifically, a patterned photoresist layer PR1 may be first formed on the surface of the second interlayer insulating layer 120, which defines locations where the stacked capacitors are to be formed. A first anisotropic etch 10 may be then performed, with the photoresist layer PR1 serving as a mask, to form the openings 120a in the second interlayer insulating layer 120. After that, the photoresist layer PR1 may be removed. In this embodiment, a plurality of conductive plates 106 may be formed on the semiconductor substrate 100 serving as capacitor terminals. Correspondingly, the same number of openings 120a are formed in the second interlayer insulating layer, each corresponding to a respective one of the conductive plates 106. Optionally, each conductive plate 106 may be at least partially exposed in the respective opening 120a, with the first interlayer insulating layer 110 remaining covered by the second interlayer insulating layer 120.

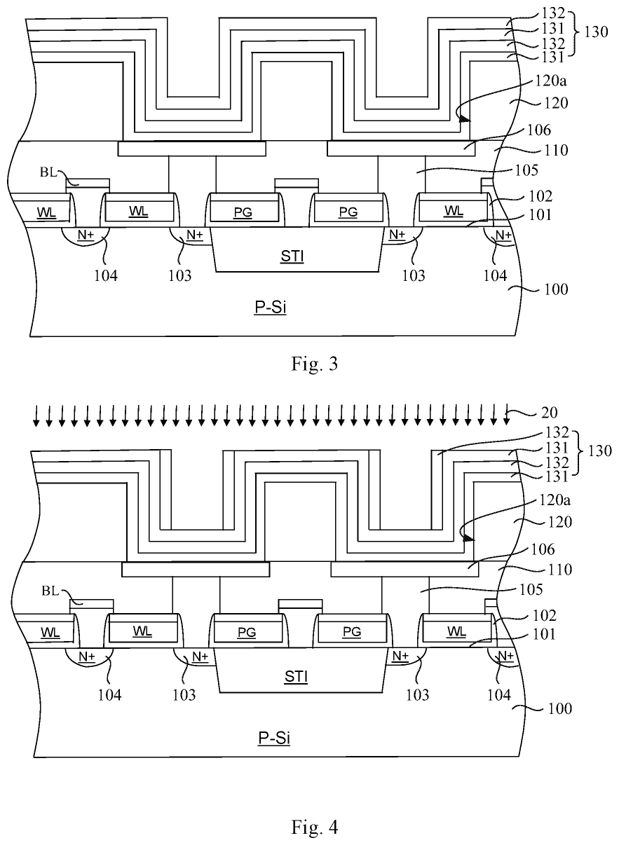

Referring to FIG. 3, a first material layer 131 and a second material layer 132 are deposited over both the surface of the second interlayer insulating layer 120 and over internal surfaces of the openings 120a. This process is repeated at least one time, resulting in the formation of a layer stack 130. The present invention is not limited to any particular total number of the first and second material layers 131, 132 in the layer stack 130. For example, tens of or even hundreds of such layers may be included. As an example, FIG. 3 shows the case of four layers, including two first material layers 131 and two second material layers 132.

A thickness of the first and second material layers 131, 132 are both smaller than a width of the openings 120a (measured as the distance between two opposite internal surfaces of each opening 120a) so that they can be stacked over the surface of the second interlayer insulating layer 120 and over the internal surfaces of the openings 120a. Each of the first and second material layers 131, 132 may have a thickness in the range of, for example, 2 nm to 20 nm. In this embodiment, the thickness of the layer stack 130 is smaller than the width of the openings 120a. For example, the layer stack 130 lined on the internal surfaces of the openings 120a may appear like a barrel.

The first and second material layers 131, 132 may be selected from suitable insulating or conductive materials. In this embodiment, they are both insulating materials, for example. The first and second material layers 131, 132 are preferred to show a relatively high etch selectivity ratio which enables desired performance of the subsequent self-aligned anisotropic etch. For example, the first material layers 131 may include silicon oxide. For example, they may be silicon oxide layers. The second material layers 132 may include silicon nitride. For example, they may be silicon nitride layers. In other embodiments, one of the first and second material layers 131, 132 may be selected as a high dielectric constant (high-k material, with a k value of greater than 3.9) material, such as Al₂O₃, Ta₂O₅, ZrO₂, LaO, BaZrO, AlO, HfZrO, HfZrON, HfLaO, HfSiON, HfSiO, LaSiO, AlSiO, HfTaO, HfTiO, (Ba,Sr)TiO₃(BST), Si₃N₄, TiO₂, etc.

Next, referring to FIGS. 4 to 7, self-aligned anisotropic etches are performed to remove portions of each second material layer 132 and portions of each first material layer 131 in the layer stack 130. As a result, the portion of the layer stack 130 remains on sidewalls of the openings 120a, and the second interlayer insulating layer 120 and the conductive plates 106 are exposed. In this embodiment, the self-aligned anisotropic etch is proceed, for example, along a normal of the semiconductor substrate 100. That is, the etch is proceed in a direction substantially perpendicular to the surface of the semiconductor substrate 100.

Specifically, referring to FIG. 4, first of all, a second anisotropic etch 20 may be carried out to etch away horizontal portions of the exposed topmost second material layer 132 in the layer stack 130 outer side of and within the openings 120a. Taking advantage of the selectivity between the second and first material layers 132, 131, the second anisotropic etch 20 can be stopped when the horizontal portions of the topmost second material layer 132 are removed and the underlying first material layer 131 is exposed. As a result, the remaining portions of the topmost second material layer 132 extend vertically and cover vertical portions of the underlying first material layer 131 in a manner of spacer (the remaining portions of the topmost second material layer 132 are tubular and extend on the vertical portions of the underlying first material layer 131). In this way, self-alignment is achieved and the use of a mask is made unnecessary.

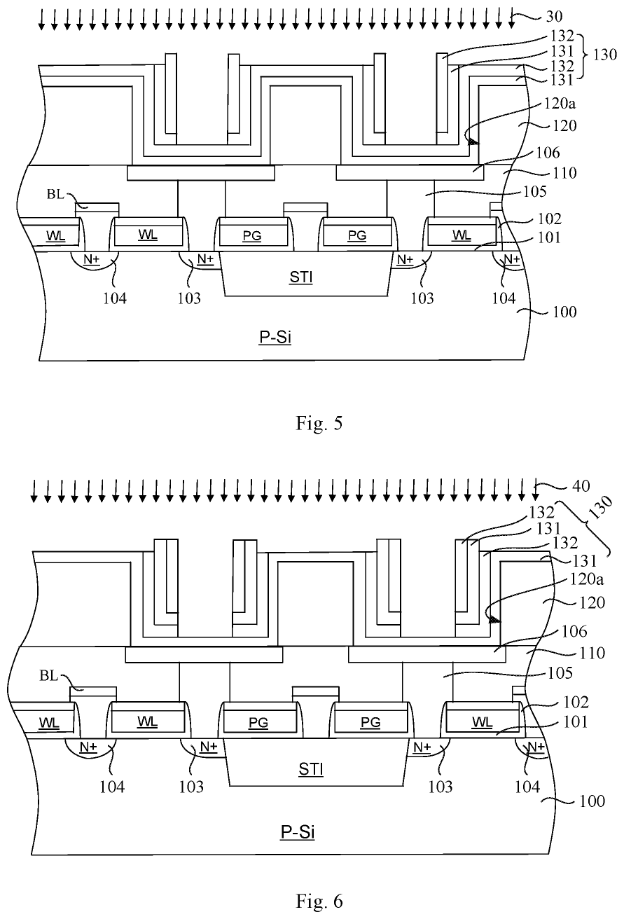

Referring to FIG. 5, a third anisotropic etch 30 may be performed to etch the first material layer 131 exposed as a result of the second anisotropic etch 20. This first material layer 131 is the second topmost layer in the layer stack 130. Taking advantage of the selectivity between the first and second material layers 131, 132, the third anisotropic etch 30 can be stopped when the exposed horizontal portions of the second-topmost first material layer 131 are removed and the underlying second material layer 132 is exposed. As a result, the remaining portions of the second-topmost first material layer 131 forms a similar structure as the last step and cover vertical portions of the underlying second material layer 132.

Referring to FIG. 6, a fourth anisotropic etch 40 may be performed to etch the second material layers 132 exposed after the completion of the third anisotropic etch 30. Here, the process step is repeated as the same as shown in FIG. 4. As a result, the exposed two second material layers 132 and one first material layer 131 overall extend vertically and cover vertical portions of the bottommost first material layer 131.

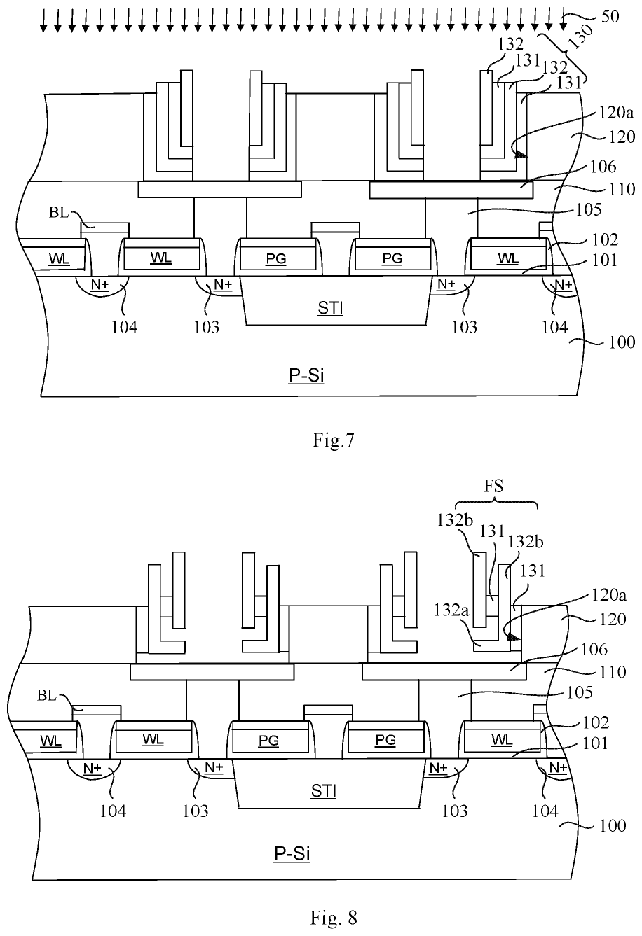

In this way, the second material layers 132 and the first material layers 131 in the layer stack 130 can be alternant etched by a self-alignment and the use of a mask is made unnecessary. Referring to FIG. 7, for example, a fifth anisotropic etch 50 may be performed to etch the bottommost first material layer 131 and the other exposed first material layer 131 in the layer stack 130. Thus, by an etching-stop mode, the fifth anisotropic etch 50 may be stopped when the second interlayer insulating layer 120 and the conductive plates 106 in the openings 120a are exposed.

In this way, portions of the layer stack 130 above the second interlayer insulating layer 120 and within the openings 120a can be removed. As a result of the above self-aligned anisotropic etches, the remaining layer stack 130 covers the sidewalls of the openings 120a. In this embodiment, at least portions of the remaining layer stack 130 extending vertically protrude beyond a top surface of the second interlayer insulating layer 120.

Referring to FIG. 8, an isotropic etch is carried out to etch back the first material layers 131 in the layer stack 130 so that surface of portions of the second material layers 132 are exposed. As a result, multilayer fin structures FS connected to the sidewalls of the openings 120a are formed. Each of the multilayer fin structures FS includes horizontal fin elements 132a and vertical fin elements 132b formed by portions of the second material layers 132 in the layer stack 130. The isotropic etch is, for example, a wet etch or a chemical dry etch (CDE).

For example, the first material layers 131 may be silicon oxide layers, and the etch-back process may use a hydrofluoric acid solution. The etch-back process may be conducted under appropriate etch conditions so that the first material layers 131 are partially removed and the surface previously covered by the removed portions are exposed. As a result of the isotropic etch, a contact area between the first and second material layers 131, 132 is reduced, and portions of the second material layers 132 not in contact with any first material layer 131 on both sides form the fin elements. Additionally, some of the fin elements extend parallel to the surface of the semiconductor substrate 100 and form the horizontal fin elements 132a, and the other fin elements extend parallel to the normal of the semiconductor substrate 100 and form the vertical fin elements 132b. The remaining second material layers 132 is connected to the remaining first material layers 131 from the etch-back process, and they both are stacked on the sidewalls of the openings 120a and constitute the multilayer fin structures FS. The multilayer fin structures FS may protrude beyond the top surface of the second interlayer insulating layer 120.

As another result of the isotropic etch, lower portions of the openings 120a are expanded, and larger portions of the conductive plates 106 are exposed. As shown in FIG. 8, for example, portions of the layer stack 130 on the conductive plates 106 may be completely removed.

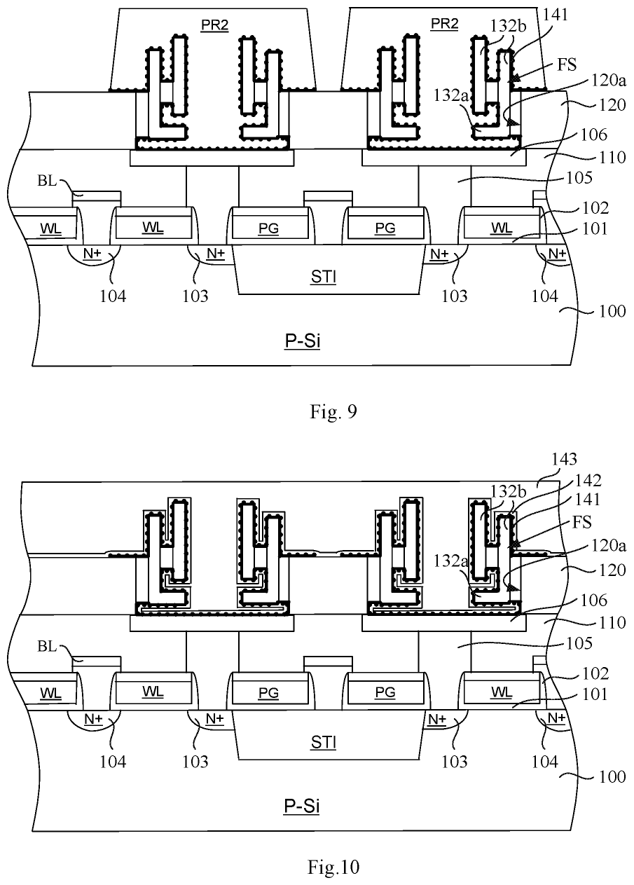

Referring to FIGS. 9 and 10, a first conductive layer 141, a capacitor dielectric layer 142 and a second conductive layer 143 are formed. The first conductive layer 141 covers surfaces of the multilayer fin structures and surface of portions of the conductive plates 106 exposed in the openings 120a (i.e., the first conductive layer 141 is connected to the capacitor terminals). The capacitor dielectric layer 142 covers the first conductive layer 141, and the second conductive layer 143 covers the capacitor dielectric layer 142.

Specifically, referring to FIG. 9, at first, a first conductive material layer may be deposited on the surfaces of the multilayer fin structures FS, the surface of portions of the conductive plates 106 exposed in the openings 120a and the surface of the second interlayer insulating layer 120. The first conductive material layer may include any one of tungsten (W), tungsten silicide (SiW), titanium (Ti), titanium nitride (TiN), doped polysilicon, rugged polysilicon or hemispherical-grained (HSG) polysilicon, or any combination thereof. The first conductive material layer may have a thickness of about 1 nm to 15 nm. In this embodiment, the first conductive material layer is, for example, N-doped polysilicon, rugged polysilicon or hemispherical-grained polysilicon. After that, a patterned photoresist layer PR2 may be formed on the first conductive material layer, which defines a range for the first conductive layer 141. Subsequently, the first conductive material layer may be etched, with the photoresist layer PR2 serving as a mask, so that portions of the second interlayer insulating layer 120 surrounding the openings 120a are exposed. Portions of the first conductive material layer surrounded by the exposed portions of the second interlayer insulating layer 120 constitute the first conductive layer 141. The first conductive layer 141 surrounding two adjacent openings 120a are separate from each other. The photoresist layer PR2 is then removed.

Subsequently, the capacitor dielectric layer 142 may be deposited over surfaces of the first conductive layer 141 and the exposed portions of the second interlayer insulating layer 120. The capacitor dielectric layer 142 may include any one of silicon oxide, silicon nitride, silicon oxynitride, hafnia (HfO) and arsenic pentoxide (As₂O₅), or any combination thereof. The capacitor dielectric layer 142 may have a thickness of about 1 nm to 10 nm.

A second conductive material layer may then be formed, which covers the capacitor dielectric layer 142 and fills up the openings 120a. A top surface of the second conductive material layer may be higher than the multilayer fin structures FS. Subsequently, the top surface of the second conductive material layer may optionally undergo a planarization (e.g., CMP) resulting in the formation of the second conductive layer 143. The second conductive layer 143 may include any one of tungsten, tungsten silicide, titanium, titanium nitride and doped polysilicon, or any combination thereof. In this embodiment, it is N-doped polysilicon, for example.

The above-described multilayer fin structures FS, first conductive layer 141, capacitor dielectric layer 142 and second conductive layer 143 constitute the stacked capacitors. The second conductive layer 143 may be commonly shared by the stacked capacitors in the openings 120a. In the stacked capacitors, each multilayer fin structure FS may include multiple horizontal fin elements 132a and multiple vertical fin elements 132b, which enable the first conductive layer 141 to have a large surface area. Moreover, there are large contact areas both between the first conductive layer 141 and the capacitor dielectric layer 142, and between the capacitor dielectric layer 142 and the second conductive layer 143, which enable the stacked capacitors to have desirably large capacitance. Further, in the method, the layer stack 130 undergoes self-aligned anisotropic and isotropic etches, which do not require the use of any photomask or the deposition of any additional layer, resulting in low manufacturing cost.

An embodiment of the present invention relates to a stacked capacitor. Referring to FIG. 10, the stacked capacitor includes:
a capacitor terminal (e.g., the conductive plate 106 shown in FIG. 10) formed on a surface of a first interlayer insulating layer 110;
a second interlayer insulating layer 120 formed over the first insulating layer 110, the second interlayer insulating layer 120 provided therein with an opening 120a, wherein the capacitor terminal is exposed at the bottom of the opening 120a;
a multilayer fin structure FS formed on a sidewall of the opening 120a, wherein the multilayer fin structure FS includes horizontal fin elements 132a and vertical fin elements 132b;
a first conductive layer 141 covering a surface of the multilayer fin structure FS and an exposed surface portion of the capacitor terminal;
a capacitor dielectric layer 142 covering a surface of the first conductive layer 141; and
a second conductive layer 143 covering a surface of the capacitor dielectric layer 142.

The stacked capacitor is formed, and the multilayer fin structure FS may include alternately stacked first and second material layers 131, 132. The first material layers 131 are, for example, silicon oxide layers, and the second material layers 132 are, for example, silicon nitride layers. Portions of the second material layers 132 not in contact with any first material layer 131 on both sides form the fin elements. Some of the fin elements extend parallel to a surface of the semiconductor substrate 100 and form the horizontal fin elements 132a, and the other fin elements extend parallel to a normal of the semiconductor substrate 100 and form the vertical fin elements 132b. An upper portion of the multilayer fin structure FS may protrude beyond a top surface of the second interlayer insulating layer 120.

An embodiment of the present invention relates to a memory device including a stacked capacitor as described above. The memory device is, for example, a dynamic random-access memory (DRAM) device.

Referring to FIG. 10, the memory device may include a semiconductor substrate 100 and a first interlayer insulating layer 110 formed over the semiconductor substrate 100. The semiconductor substrate 100 may include isolation (e.g., STI) regions and an active area defined by the isolation regions. The memory device may further include a MOS transistor formed on a surface of the active area. The MOS transistor may include a gate and, formed in the active area on opposite sides of the gate, a source region 103 and a drain region 104. The memory device may further include a contact plug 105 and a conductive plate 106. The contact plug 105 is formed in the first interlayer insulating layer 110 and is connected at one end thereof to the source region 103. The conductive plate 106 formed on a surface of the first interlayer insulating layer 110 is connected to the other end of the contact plug 105. In this embodiment, the conductive plate 106 serves as a capacitor terminal of the stacked capacitor.

In the stacked capacitor and the memory device provided in embodiments of the present invention, the multilayer fin structure FS can include multiple horizontal fin elements 132a and multiple vertical fin elements 132b, which enable the first conductive layer 141 to have a large surface area. Moreover, there are large contact areas both between the first conductive layer 141 and the capacitor dielectric layer 142, and between the capacitor dielectric layer 142 and the second conductive layer 143, which help increase the capacitance of the stacked capacitor. Further, the stacked capacitor can be fabricated at low cost.

It is to be noted that the embodiments disclosed herein are described in a progressive manner, with the description of each embodiment focusing on its differences from others. Reference can be made between the embodiments for their identical or similar parts.

The foregoing description is merely that of several preferred embodiments of the present invention and is not intended to limit the scope of the claims of the invention in any way. Any person of skill in the art may make various possible variations and changes to the disclosed embodiments in light of the methodologies and teachings disclosed hereinabove, without departing from the spirit and scope of the invention. Accordingly, any and all such simple variations, equivalent alternatives and modifications made to the foregoing embodiments based on the essence of the present invention without departing from the scope of the embodiments are intended to fall within the scope of protection of the invention.

What is claimed is:

1. A method for making a stacked capacitor, comprising:
providing a capacitor terminal formed on a surface of a first interlayer insulating layer,
forming a second interlayer insulating layer over the capacitor terminal and the first interlayer insulating layer;
forming an opening penetrating through the second interlayer insulating layer, wherein the capacitor terminal is exposed in the opening;
forming a layer stack by stacking a first material layer and a second material layer over a surface of the second interlayer insulating layer and over an internal surface of the opening and repeating the stacking at least one time;
removing portions of the second material layers and portions of the first material layers by performing a self-aligned anisotropic etch, wherein a remaining layer stack covers a sidewall of the opening and exposes the second interlayer insulating layer and the capacitor terminal;
forming a multilayer fin structure connected to the sidewall of the opening by performing an isotropic etch that is used to etch back the first material layers in the layer stack and to expose surfaces of portions of the second material layers, wherein the multilayer fin structure comprises horizontal fin elements and vertical fin elements formed by portions of the second material layers; and
forming a first conductive layer, a capacitor dielectric layer and a second conductive layer, wherein the first conductive layer covers a surface of the multilayer fin structure and a surface of the capacitor terminal exposed in the opening, wherein the capacitor dielectric layer covers a surface of the first conductive layer, the second conductive layer covering the capacitor dielectric layer.

2. The method of claim 1, wherein the isotropic etch is a wet etch or a chemical dry etch.

3. The method of claim 1, wherein each of the first and second material layers is an insulating material.

4. The method of claim 1, wherein the first material layer comprises silicon oxide and the second material layer comprises silicon nitride.

5. The method of claim 1, wherein each of the first and second material layers has a thickness in a range of from 2 nm to 20 nm.

6. The method of claim 1, wherein a thickness of the layer stack is smaller than a width of the opening.

7. The method of claim 1, wherein the first interlayer insulating layer is formed over a semiconductor substrate comprising isolation regions and an active area defined by the isolation regions, wherein the active area is formed therein with source and drain regions, and wherein at least one of the source and drain regions is connected to the capacitor terminal.

8. The method of claim 7, wherein a MOS transistor is formed in the active area of the semiconductor substrate, wherein the MOS transistor comprises a gate, and a source region and a drain region formed in the active area on opposite sides of the gate, wherein the first interlayer insulating layer is formed therein with a contact plug and with a conductive plate, wherein the contact plug is connected to the source region at a first end and the conductive plate is connected to a second end of the contact plug, and wherein the conductive plate serves as the capacitor terminal.

9. The method of claim 1, wherein the first conductive layer has a thickness of from 1 nm to 15 nm, and the capacitor dielectric layer has a thickness of from 1 nm to 10 nm.

10. The method of claim 1, wherein the first conductive layer comprises any one of tungsten, tungsten silicide, titanium, titanium nitride, doped polysilicon, rugged polysilicon and hemispherical-grained polysilicon, or any combination thereof.

11. The method of claim 1, wherein the capacitor dielectric layer comprises any one of silicon oxide, silicon nitride, silicon oxynitride, hafnia and arsenic pentoxide, or any combination thereof.

12. The method of claim 1, wherein the second conductive layer comprises any one of tungsten, tungsten silicide, titanium, titanium nitride and doped polysilicon, or any combination thereof.

13. The method of claim 1, wherein an upper portion of the multilayer fin structure protrudes beyond a top surface of the second interlayer insulating layer.

14. The method of claim 1, wherein forming the first conductive layer, the capacitor dielectric layer and the second conductive layer comprises:
depositing a first conductive material layer over the surface of the multilayer fin structure, the surface of the capacitor terminal exposed in the opening and the surface of the second interlayer insulating layer;
forming the first conductive layer by etching the first conductive material layer to expose a portion of the second interlayer insulating layer surrounding the opening;
depositing the capacitor dielectric layer over the surface of the first conductive layer and a surface of the exposed portion of the second interlayer insulating layer;
forming a second conductive material layer over a surface of the capacitor dielectric layer, wherein the second conductive material layer fills up the opening and has a top surface higher than the multilayer fin structure; and
forming the second conductive layer by planarizing the top surface of the second conductive material layer.

15. A stacked capacitor, comprising:
a capacitor terminal formed on a surface of a first interlayer insulating layer;
a second interlayer insulating layer formed over the first insulating layer, wherein the second interlayer insulating layer has an opening penetrating therethrough, and wherein the capacitor terminal is exposed in the second interlayer insulating layer;
a multilayer fin structure connected to a sidewall of the opening and exposing the capacitor terminal at a bottom of the opening, wherein the multilayer fin structure comprises horizontal fin elements and vertical fin elements;
a first conductive layer covering a surface of the multilayer fin structure and a surface of the exposed capacitor terminal;
a capacitor dielectric layer covering a surface of the first conductive layer; and
a second conductive layer covering the capacitor dielectric layer.

16. The stacked capacitor of claim 15, wherein the multilayer fin structure comprises alternately stacked first material layer and second material layer, and wherein the horizontal and vertical fin elements are formed by portions of the second material layers.

17. The stacked capacitor of claim 16, wherein the first material layer comprises silicon oxide and the second material layer comprises silicon nitride.

18. A memory device comprising the stacked capacitor of claim 15.

19. The memory device of claim 18, comprising:
a semiconductor substrate over which the first interlayer insulating layer is formed, wherein the semiconductor substrate comprises isolation regions and an active area defined by the isolation regions;
a MOS transistor formed in the active area, wherein the MOS transistor comprises a gate, and a source region and a drain region formed in the active area on opposite sides of the gate,
a contact plug formed in the first interlayer insulating layer, wherein the contact plug is connected to the source region at a first end; and
a conductive plate formed on a surface of the first interlayer insulating layer, wherein the conductive plate is connected to a second end of the contact plug, and the conductive plate serving as the capacitor terminal.
